(19) United States
(12) Patent Application Publication
(10) Pub. No.: US 2014/0000713 A1
(43) Pub. Date: Jan. 2, 2014

(54) MECHANICALLY STABLE DEVICE BASED ON NANO/MICRO WIRES AND HAVING IMPROVED OPTICAL PROPERTIES AND PROCESS FOR PRODUCING IT

(71) Applicants: David Kohen, Villeurbanne (FR); Nicolas Karst, Folkling (FR); Simon Perraud, Bandol (FR)

(72) Inventors: David Kohen, Villeurbanne (FR); Nicolas Karst, Folkling (FR); Simon Perraud, Bandol (FR)

(73) Assignee: COMMISSARIAT A L'ENERGIE ATOMIQUE ET AUX ENERGIES ALTERNATIVES, Paris (FR)

(21) Appl. No.: 14/005,375

(22) PCT Filed: Mar. 6, 2012
(86) PCT No.: PCT/FR2012/000078

§ 371 Date: Sep. 16, 2013

(30) Foreign Application Priority Data
Mar. 17, 2011 (FR) 1100804

(51) Int. Cl. H01L 31/0224; H01L 31/0352; H01L 31/0312

(52) U.S. Cl. CPC H01L 31/022408; H01L 31/0312; H01L 31/0352
USPC 136/261; 257/448; 438/98

(57) ABSTRACT

A device includes a plurality of wires of nanometric or micrometric dimensions formed by a semiconductor material chosen from silicon, germanium and a silicon and germanium alloy. The device further includes pellets enhancing the mechanical strength and the optical absorption properties of the device. The pellets have a diameter between 100 nm and 1 μm and are formed by spherical agglomerates of zinc oxide particles with a diameter between 10 mn and 200 nm. The pellets are in particular obtained by immersing the wires in a bath containing an alcohol-based solvent and zinc acetate under temperature and pressure conditions keeping the alcohol-based solvent in the liquid state and by thermal annealing of the wires transforming the zinc acetate into zinc oxide.

### BACKGROUND OF THE INVENTION

The invention relates to a device comprising wires of nanometric or micrometric dimensions and formed by a semiconductor material chosen from silicon, germanium and a silicon and germanium alloy, its fabrication method and the use thereof in a photovoltaic cell or a photonic component.

### STATE OF THE ART

Nanowires or microwires made from semiconductor material present mechanical, optical and electrical properties making them attractive in numerous technological fields. Over the last few years, they have been intensively studied in fields such as the fields of electronics, optoelectronics and sensors. Furthermore, they have recently been used in energy recovery devices such as devices converting thermal, mechanical or solar energy into electricity. In particular, a promising field for semiconductor wire-based structures is the photovoltaic field.

The article “Challenges and Prospects of Nanopillar-Based Solar Cells” by Zhiyong Fan et al. (Nano Res (2009) 2:829-843) reviews the continuous progress of photovoltaics based on nanowires (also abbreviated to NWs), with a view to integration of the latter for efficient and reasonably-priced solar cell modules.

Among the different photovoltaic structures reviewed in the article by Zhiyong Fan et al., a new type of dye-sensitized solar cells (DSSC) can be cited in which the film of nanoparticles made from titanium oxide (TiO₂) or zinc oxide (ZnO) is replaced by a bed of vertically oriented monocrystalline zinc oxide nanowires. However, the article by Zhiyong Fan et al. indicates that the nanowire-based DSSCs remain greatly inferior to the best nanoparticle-based DSSCs, even when they are covered with a surface coating designed to enhance the efficiency of the DSSCs.

For example purposes, the article “Wet-Chemical Route to ZnO Nanowire-layered Basic Zinc Acetate/ZnO Nanoparticle Composite Film” by Chen-Hao Ku et al. (Crystal Growth & Design, 2008, Vol. 8, N° 1, 283-290) synthesizes and studies a composite film formed by a bed of zinc oxide nanowires covered by a film noted LBZA/ZnO NPs and composed of zinc oxide and hydroxidated zinc acetate nanoparticles, also known under the acronym LBZA. The LBZA/ZnO NPs film is produced by immersing the bed of zinc oxide nanowires in a solution of methanol and zinc acetate, at 60° C. for a time varying from 14 hours to 24 hours. Photovoltaic measurements show that such a composite film could be a promising candidate as photoanode in a DSSC, for an immersion time of the bed of nanowires, in the chemical bath, of less than 15 hours. Formation of the composite film seems to rely on a heterogeneous nucleation of the LBZA structure at the crystalline surface of the ZnO nanowires. If 15 hours of immersion are exceeded, a secondary nucleation of LBZA takes place at the surface of the composite film formed by the bed of ZnO nanowires and the LBZA/ZnO NPs film, which causes a decline in the photovoltaic performances of the composite film.

The article by Zhiyong Fan et al. referred to above also mentions nanowire-based, in particular silicon-based, inorganic solar cells. It relates that, although silicon is a dominant material in conventional flat solar cells, it is not an ideal material for nanowire-based solar cells on account of its low optical absorption coefficient and its narrow bandgap.

Furthermore, nanowire-based devices and in particular nanowire-based devices made from semiconductor materials such as silicon, are fragile structures, without any mechanical strength, which makes handling of the latter complicated. The space between the nanowires moreover does not participate in optical absorption and can be considered as being lost. Finally, the electric contact between all the nanowires has to be established to achieve a functional device.

In the article “Enhanced absorption and carrier collection in Si wire arrays for photovoltaic applications” by Michaels D. Kelzenberg et al. (Nature Materials 9,239-244 (2010)), the optical absorption properties of structures comprising silicon nanowires obtained by chemical vapor deposition are studied. In particular, silicon nanowires are obtained by a Solid Liquid Vapor growth process and are then coated in a film of PDMS (polydimethylsiloxane). To enhance the optical absorption, it is in particular proposed to perform an antireflective conformal deposition of SiNₓ on the peaks and sides of the nanowires before encapsulation in the PDMS and/or to add alumina particles in the PDMS film so that the particles diffuse light to the nanowires. However, the solutions proposed in this article, in particular to enhance the optical absorption, are not entirely satisfactory. PDMS and alumina particles are in fact electrically insulating materials. Electrical conduction in this type of structure can therefore only be performed via the peaks of the silicon nanowires. Furthermore, the fabrication process of these structures is long and costly, especially for structures comprising a large surface.

### OBJECT OF THE INVENTION

The object of the invention consists in proposing a device comprising a plurality of wires of nanometric or micrometric dimensions formed by a semi-conductor material chosen from silicon, germanium and a silicon-germanium alloy, remedying the drawbacks of the prior art. In particular, the object of the invention is to propose a device presenting a mechanical stability and enhanced optical properties, with the capacity of having an enhanced electrical conduction.

According to the invention, this object is achieved by the appended claims.

### BRIEF DESCRIPTION OF THE DRAWINGS

Other advantages and features will become more clearly apparent from the following description of particular embodiments of the invention given for non-restrictive example purposes only and represented in the appended drawings, in which:

FIGS. 1 to 4 schematically represent, in cross-section, different steps of fabrication of a device comprising a bed of vertical silicon wires surrounded by ZnO pellets.

FIG. 5 is a snapshot obtained by scanning electron microscopy with an enlargement×6000 of a device comprising a bed of vertical silicon wires.

FIG. 6 is a snapshot obtained by scanning electron microscopy with an enlargement×4000 of a device comprising a bed of vertical silicon wires surrounded by ZnO pellets.

FIG. 7 is a snapshot obtained by scanning electron microscopy with an enlargement×80000 of the ZnO pellets visible on the snapshot according to FIG. 6.

FIG. 8 schematically illustrates, in cross-section, a photovoltaic cell comprising a device comprising a bed of vertical silicon wires surrounded by ZnO pellets arranged in homogenous manner along the wires.

FIG. 9 represents the variation of the current versus the voltage for a photovoltaic cell comprising a device with a bed of silicon wires without ZnO pellets (FIG. 9A) and with ZnO pellets (FIG. 9B).

### DESCRIPTION OF PREFERRED EMBODIMENTS OF THE INVENTION

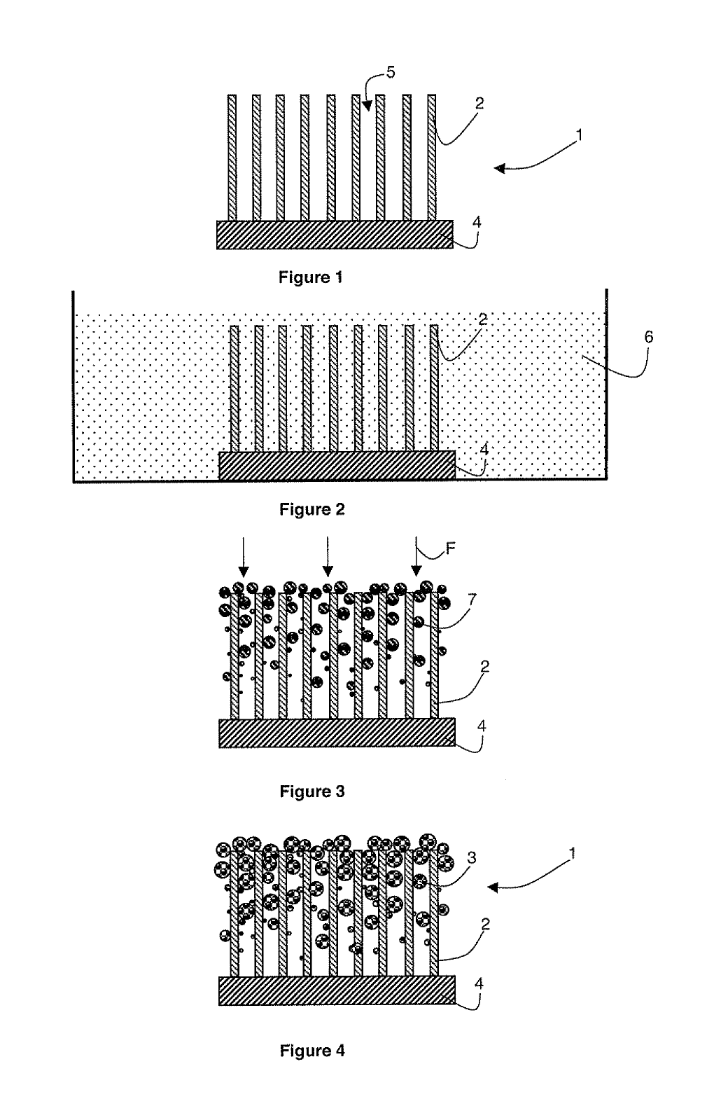

As illustrated in FIGS. 1 to 4, a device 1 comprising a plurality of wires 2 is treated by wet process and by annealing in order to form ZnO pellets 3 at the surface of wires 2.

Wires 2 are formed by a semiconductor material chosen from silicon, germanium and a germanium-silicon alloy. The semiconductor material can advantageously be electronically n-doped or p-doped, depending on the applications of the device. Wires 2 are more particularly wires having nanometric dimensions (nanowires) and/or micrometric dimensions (microwires). They have a diameter for example comprised between 5 nm and 10 μm and a length of about 500 nm to 100 μm.

The wires can further have a crystalline structure, for example monocrystalline or polycrystalline. They can also be of amorphous structure (a-Si) which may be hydrogenated (noted a-Si:H), i.e. with a large hydrogen content for example comprised between 1% and 20%.

The structure of the wires depends essentially on the fabrication method used. For example, the wires can be obtained by a vapor-liquid-solid growth method (CVD assisted by a metallic catalyst such as aluminium or gold), by chemical or physical etching or by molecular beam epitaxy. They are then of monocrystalline or polycrystalline structure. They can also be obtained by etching, for example by Reactive-Ion Etching (RIE), of a layer formed by the semiconductor material chosen to form the wires. In this case, the wires will be of amorphous or crystalline structure, depending on the structure of the semiconductor material forming the layer designed to be etched.

When the wires have a crystalline structure, in known manner, their surface oxidizes very easily in contact with air. A superficial oxide (native oxide) is then formed at the surface of the wires and presents an amorphous structure. In this case, the amorphous oxide at the surface of the wires is preferably preserved to produce pellets 3.

Consequently, in the case of wires of crystalline structure as in the case of wires of amorphous structure, the pellets 3 are advantageously formed and therefore arranged on an amorphous surface of the wires.

According to an alternative, a layer of amorphous semiconductor material can also be deposited on the surface of at least a part of the wires. In this case, the wires can be either of crystalline structure or of amorphous structure, depending on the applications. Deposition is for example a conformal deposition of hydrogenated amorphous silicon performed for example by PECVD (Plasma Enhanced Chemical Vapor Deposition). In this case, pellets 3 are also formed (and therefore arranged) on an amorphous surface. This surface is also considered as being the surface of the wires.

Thus, in general manner, the surface from which ZnO pellets 3 are formed is preferably amorphous.

In FIGS. 1 to 4, wires 2 are supported by a substrate 4, which can be made of semiconductor or metallic material. They are further arranged vertically with respect to substrate 4. However, the direction of growth of the wires could, depending on the applications, be different. It could for example be random or in all the existing directions of growth. Furthermore, on account of the conformal nature of the ZnO deposition, the wires could also present bends or changes of direction. Finally, wires 2 are separated from one another by spaces 5 having a mean width advantageously comprised between 100 nm and 15 μm, and preferably comprised between 100 nm and 1 μm.

Pellets 3 are formed at the advantageously amorphous surface of wires 2 and a part of said pellets 3 occupies the spaces 5 separating wires 2. These pellets 3 are obtained by immersing the wires 2 in a bath containing a solvent and zinc acetate under temperature and pressure conditions keeping the solvent in liquid state. Immersion of the wires in the bath is advantageously performed without stirring.

FIG. 2 illustrates this immersion step of wires 2 in a bath 6 containing the zinc acetate in solution. The zinc acetate can be diluted, with for example a concentration comprised between 0.01 and 0.5 mol/L, or bath 6 can be filled with a solution saturated with zinc acetate. In both cases, the solvent used is an alcohol-based solvent such as methanol or ethanol. The immersion step is further in particular performed in a sealed enclosure at atmospheric pressure and keeping the bath at a temperature comprised between −10° C. and +65° C. The duration of the immersion step is further preferably comprised between 2 hours and 48 hours, in particular for a solution comprising a zinc acetate concentration comprised between 0.01 and 0.5 mol/L. The duration of the immersion step can be reduced by regularly renewing the chemical bath, for example every hour.

Such an immersion enables particles 7 of hydroxidated zinc acetate, also known under the acronym LBZA and complying with the formula Zn(OH)ₓ—(CH₃COO₂)_{y}.zH₂O), to be bound to the surface of wires 2.

As illustrated in FIG. 3, the device comprising wires 2 with LBZA particles 7 is then removed from bath 6 and undergoes thermal annealing designed to transform LBZA particles 7 into zinc oxide-based pellets 3. The thermal annealing is symbolized by arrows F in FIG. 3. It is advantageously performed at a temperature comprised between 300° C. and 600° C. Thermal annealing is for example performed with a progressive temperature increase with a gradient of 80° C./minute until stabilization is reached at a temperature of 450° C. for 10 minutes.

Thermal annealing enables pellets 3 to be obtained at the surface of wires 2.

Furthermore, it has been found that pellets 3 are each composed by an agglomerate of zinc oxide particles. This agglomerate is spherical and it can be hollow or solid. The zinc oxide particles are zinc oxide nanoparticles, in particular having a diameter comprised between 10 nm and 200 nm and advantageously comprised between 100 nm and 200 nm. Furthermore, as illustrated in FIG. 4, pellets 3 can have variable diameters, comprised in a range of 100 nm to 1 μm. The zinc oxide particles forming these pellets 3 then also have variable diameters ranging from 10 nm to 200 nm, while still remaining smaller than the diameter of the pellet which they form. The zinc oxide particles forming by agglomeration a pellet having a diameter of 100 nm therefore necessarily have a diameter of less than 100 nm. It can for example be comprised in a range of 10 nm to 50 nm.

It has also been observed that the particular morphology of pellets 3 is obtained before annealing. Before annealing, LBZA particles 7 do in fact present the particular morphology of pellets 3: particles 7 are also formed by agglomerates of LBZA particles of smaller dimensions. LBZA particles 7 on the other hand have smaller dimensions than pellets 3. Their diameter is advantageously 40% to 75% smaller than that of pellets 3 obtained after annealing. The same is true for the particles of smaller dimensions (LBZA nanoparticles) constituting LBZA particles 7 compared with the zinc oxide nanoparticles. The LBZA nanoparticles in particular have a variable diameter comprised in the following range: 4 nm-150 nm.

Furthermore, as illustrated in FIG. 4, pellets 3 were formed by growth from the advantageously amorphous surface of wires 2. Thus, in FIG. 4, the distribution of the pellets is localized. A part of pellets 3 are located in spaces 5, whereas another part of pellets 3 can be located at the peak of wires 2.

According to an alternative, the distribution of pellets 3 along wires 2 could be different. It could be homogenous along the wires, in the spaces separating them. This would then enable an improved optical effect to be obtained. Such a homogenous distribution can be obtained by modifying the dimensions of the wires, their separating distance and the concentration of zinc acetate in the chemical bath.

Finally, the density and disposition of pellets 3 advantageously enable adjacent nanowires to be placed in contact with one another, which can allow electrical connection between the nanowires, in particular when the electronic conduction properties of pellets 7 are modified. This is particularly advantageous in a large number of fields of application, such as the field of photovoltaic cells, with radial or axial junction, or even the field of photonic components. The electronic conduction properties of pellets 7 can more particularly be modified by adding doping elements to the zinc oxide nano-particles in order to make the latter electrically conducting. The doping elements are for example aluminium, boron, magnesium or chlorine particles. Their solid or liquid precursor is then advantageously added in chemical bath 6. For example, doping with aluminium can be obtained by adding hydrated aluminium nitrate (Al(NO₃)₃H₂O) in bath 6.

For illustration purposes, vertical silicon nanowires are produced on a substrate formed by a silicon wafer of <111> crystalline orientation and with a resistivity comprised between 14 and 22 Ohm·cm. They are then treated by immersion in a zinc acetate bath and by thermal annealing.

In a first step, the silicon nanowires are synthesized. The substrate undergoes chemical cleaning in a bath of H₂SO₄ (30%) and H₂O₂ in a proportion of 2:1, for 10 minutes, followed by rinsing with deionized water for 5 minutes. Cleaning of the substrate in a HF bath (10%), followed by the same rinsing with water are then performed. A layer of aluminium with a thickness of 10 nm is then deposited on the surface of the substrate prepared in this way, by evaporation in a vacuum. Vertical silicon nanowires are then formed by chemical vapor deposition (CVD). The deposition conditions are as follows:

total pressure of the CVD deposition chamber: 0.040 MPa,

substrate temperature: 600° C.

gas precursors: silane (SiH₄) and hydrogen (H₂) with the following partial pressures: silane 866.6 Pa and hydrogen 0.0391 MPa

deposition time: 5 minutes.

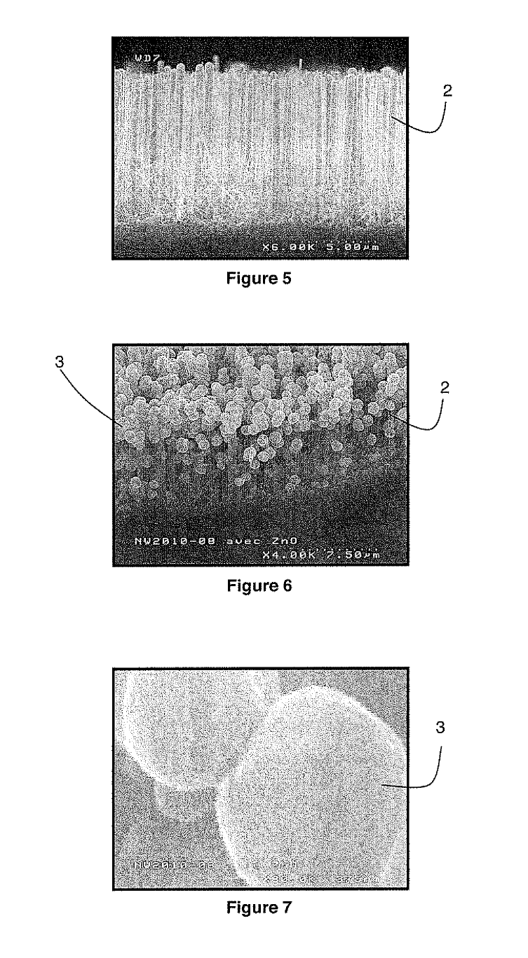

The structure obtained in this way was characterized by scanning electron microscopy (FIG. 5). The obtained nanowires have diameters comprised between 100 nm and 600 nm, with a mean distance between two nanowires of about 3 μm and a mean length of the nanowires of about 15 μm.

In a second step, the ZnO pellets are formed at the surface of the nanowires. For this, the silicon wafer provided with the vertical nanowires is immersed in a chemical bath, without stirring, kept at 60° C. and at atmospheric pressure. Immersion is performed for 48 hours and the bath is formed by zinc acetate (concentration 0.15 mol/L) diluted in methanol.

The wafer is then removed from the chemical bath and directly undergoes thermal annealing at 450° C., for 10 minutes, in air. For this, it is arranged on a heating plate. Observation by scanning electron microscopy (FIG. 6) shows that the surface of each nanowire is covered by about 5 to 20 pellets. In addition, the mean diameter of these pellets is comprised between 700 nm and 800 nm. Furthermore, a greater enlargement on the SEM snapshot represented in FIG. 7 shows that the pellets are formed by spherical agglomerates of considerably smaller particles (typically 20 nm).

Producing a device comprising a plurality of nanowires and/or of microwires, the surface of which is covered with pellets having a diameter comprised between 100 nm and 1 μm and formed by spherical agglomerates of zinc oxide particles with a diameter comprised between 10 nm and 200 nm, is advantageous in particular in terms of improvement of the strength of the device and of its optical performances. Furthermore, the implementation techniques involved (immersion in a bath and thermal annealing) are simple, inexpensive, commonplace techniques enabling implementation to be envisaged on an industrial scale.

The presence of pellets 3 effectively gives the device a mechanical strength, which improves its handling. The wires made from semiconductor material of nanometric or micrometric dimensions are indeed by nature fragile. For example, the strength of a structure comprising silicon nanowires with ZnO pellets was tested and compared with that of the same structure without ZnO pellets. The mechanical strength testing consists in placing the structure on a flat surface directing the nanowires towards said flat surface. The support of the structure (typically the silicon wafer) then presses on the nanowires. The structures handled in this way were then observed by scanning electron microscopy. These observations enabled it to be observed that the nanowires of the structure not containing the ZnO pellets fractured under the weight of the support, whereas those of the structure with the ZnO pellets remained intact.

The presence of ZnO pellets 3, when the latter are distributed in a homogenous manner on the wires, also enhances absorption of light by wires 2. The ZnO nanoparticles and pellets 3 do in fact interact with light radiation. This light is therefore diffused and can therefore be absorbed by the wires instead of passing directly through the space between the wires. Furthermore, the wavelength spectrum able to be diffused is broadened due to the presence of particles of two different dimensions corresponding to the diameter of the nanoparticles and of the pellets. The presence of an agglomerate of nanoparticles therefore enables diffusion of a larger range of wavelengths than in the case of non-agglomerated nanoparticles.

Finally, the fact that ZnO pellets 3 are present in spaces 5 separating wires 2 is also advantageous, as this enables the optically active surface of the device to be increased. The space separating the wires is then no longer considered as being a wasted space.

These advantages are in particular very profitable for producing a photovoltaic cell, in particular an inorganic cell, and using a bed of nanowires made from silicon, germanium or a Si—Ge alloy.

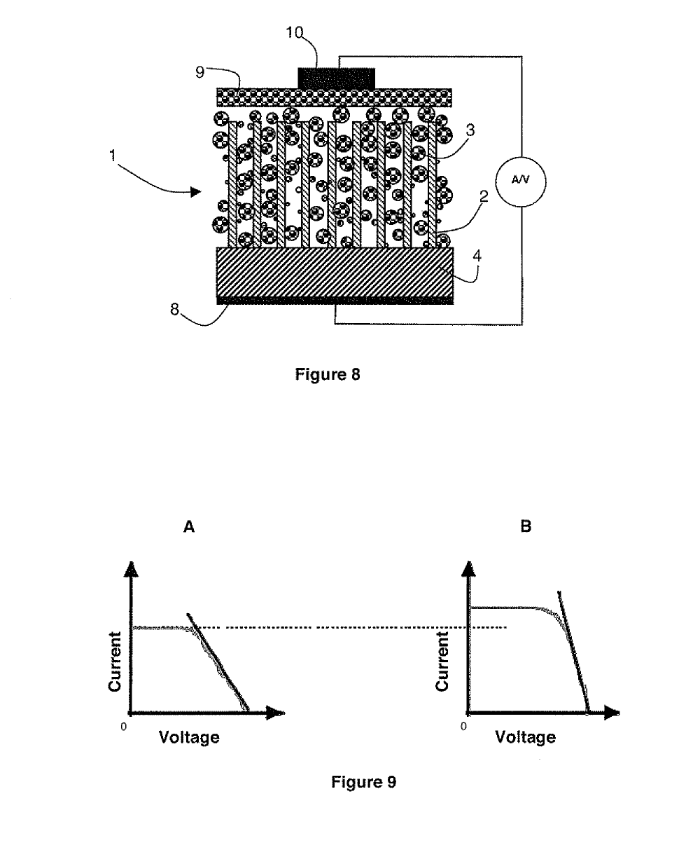

For example, a photovoltaic cell with a radial junction made from silicon was produced. Its structure is illustrated in FIG. 8. After a growth step of monocrystalline silicon nanowires 2 has been performed on a highly doped silicon substrate 4, the radial junction is produced by plasma enhanced chemical vapor deposition of a hydrogenated amorphous silicon layer. Radial junction nanowires 2 are obtained. Growth of aluminium-doped ZnO pellets 3 is performed in a chemical bath with the same method as that described in the foregoing and by adding an aluminium precursor in the bath. In this embodiment, ZnO pellets 3 are distributed in homogenous manner along nanowires 2. An aluminium electrode 8 with a thickness of 100 nm is then deposited on the rear surface of substrate 4 by evaporation. For the front surface of substrate 4, an aluminium-doped ZnO coating 9 with a thickness of 500 nm is produced by cathode sputtering. Coating 9 is then arranged on the peaks of nanowires 2 provided with pellets 3. Finally a nickel/aluminium metallic electrode 10 with a thickness of 200 nm is then deposited on coating 9 by evaporation.

The current-voltage characteristics of this cell (see FIG. 9B) are then plotted and compared with those of the same cell without pellets 3 (see FIG. 9A).

Without ZnO pellets 3, the slope of the current versus voltage plot in FIG. 9A is gentle. This shows a high series resistance due to the fact that the nanowires are not all connected to one another and/or that only the peak of the nanowires is in contact with the top electrode 10. Furthermore, a fairly weak open-circuit current is obtained, as a large part of the light passes between the nanowires.

With pellets 3, it can be observed that the series resistance is greatly reduced, as it drops from a few hundred Ohms to a few Ohms. This resistance decrease is due to the fact that the nanowires are connected to one another and that the pellets are arranged in homogenous manner along the nanowires.

Furthermore, the open-circuit current is also improved as a large part of the light is diffused by the ZnO pellets and absorbed by the wires. The resulting current improvement can then reach values between 10% and 50%, which assumes that an improvement of the energy conversion efficiency for the photovoltaic cell with nanowires is obtained (increase from 1% to 5-10% by addition of ZnO nanoparticles). The mechanical strength is enhanced.

A device with nanowires or microwires as described above can be used in other fields than that of photovoltaics. It can in particular be used in photonic components requiring maximization of photons. For example purposes, it can be used in a nanowire photodetector (or photodiode) in which a junction is created to detect the presence of photons. The current measured at the terminals of the device then increases when a photon is absorbed. Furthermore, improvement of the mechanical strength of a nanowire or microwire structure by formation of ZnO pellets can also be temporary for the purposes of protecting the structure during transport. In this case, the pellets are then eliminated by selective wet etching, typically in a NH₄Cl bath.

This device can also be used solely for its electrical conduction function. It can for example constitute an electrode (for a battery, hydrogen production device, etc.).

1-17. (canceled)

18. A device comprising a plurality of wires of nanometric or micrometric dimensions and formed by a semiconductor material chosen from silicon, germanium and a silicon-germanium alloy, said device comprising pellets having a diameter comprised between 100 nm and 1 μm formed by spherical agglomerates of zinc oxide particles with a diameter comprised between 10 nm and 200 nm arranged at the surface of the wires.

19. The device according to claim 18, wherein the surface of the wires is amorphous.

20. The device according to claim 18, wherein the diameter of the zinc oxide particles is comprised between 100 nm and 200 nm.

21. The device according to claim 18, wherein the wires are separated from one another by spaces in which at least a part of the pellets are arranged.

22. The device according to claim 21, wherein the spaces separating adjacent wires have a mean width comprised between 100 nm and 15 μm.

23. The device according to claim 18, wherein adjacent wires are placed in contact with one another through the pellets.

24. The device according to claim 18, wherein the wires are supported by a substrate made from semiconductor or metallic material.

25. The device according to claim 18, wherein the zinc oxide particles comprise a doping element making them electrically conductive.

26. A method for producing a device according to claim 18, wherein the pellets are formed at the surface of the wires by the following steps:
immersing the wires in a bath containing an alcohol-based solvent and zinc acetate, under temperature and pressure conditions keeping the alcohol solvent in the liquid state,
and thermal annealing of the wires after removal of the latter from the bath, transforming the zinc acetate into zinc oxide.

27. The method according to claim 26, wherein that the immersion step is performed in a sealed enclosure, at atmospheric pressure, keeping the bath at a temperature comprised between −10° C. and +65° C.

28. The method according to claim 26, wherein the duration of the immersion step is comprised between 2 hours and 48 hours.

29. The method according to claim 26, wherein the thermal annealing step is performed at a temperature comprised between 300° C. and 600° C.

30. The method according to claim 26, wherein at least a part of the wires are formed by crystalline wires and in that the surface of the crystalline wires is oxidized in contact with air before the immersion step.

31. The method according to claim 26, wherein a layer of amorphous semiconductor material is deposited on the surface of at least a part of the wires.

32. The method according to claim 26, wherein at least a part of the wires are formed by an etching operation in a layer formed by the semiconductor material.

33. A photovoltaic cell comprising a device according to claim 18.

34. A photonic component comprising a device according to claim 18.
